(19) United States
(12) Patent Application Publication
(10) Pub. No.: US 2026/0304647 A1
(43) Pub. Date: Oct. 1, 2026

(54) DISPLAY DEVICE

(71) Applicant: LG ELECTRONICS INC., Seoul (KR)

(72) Inventor: Chanwoo KIM, Seoul (KR)

(73) Assignee: LG ELECTRONICS INC., Seoul (KR)

(21) Appl. No.: 19/481,122

(22) PCT Filed: Apr. 4, 2024
(86) PCT No.: PCT/KR2024/095678

§ 371 Date: Nov. 3, 2025

(30) Foreign Application Priority Data
Jun. 2, 2023 (KR) 10-2023-0071669

(51) Int. Cl. H05K 5/02

(52) U.S. Cl. CPC H05K 5/0204

(57) ABSTRACT

This display device comprises: a main body housing having a display unit for outputting an image mounted on the front thereof; strap rings formed on sides of the main body housing; a strap having both ends fastened to the strap rings; an elastic holder including strap holes into which the strap is inserted; and a pair of holder coupling parts formed on the rear surface of the main body housing and into which both ends of the elastic holder are inserted, wherein when both ends of the elastic holder are inserted into the pair of holder coupling parts, the elastic holder supports the rear surface of the main body housing so as to stand the main body housing on a mounting surface. Accordingly, the display device can be carried and mounted with one elastic holder, thereby improving portability and usability.

### TECHNICAL FIELD

The present disclosure relates to a display device that may be freely moved and easily mounted while minimizing a mounting space.

### BACKGROUND

With growth of information society, demand for various display devices has increased. In order to satisfy such demand, in recent years, a liquid crystal display (LCD), a field emission display (FED), a plasma display panel (PDP), and an electroluminescent device have been developed as display devices.

A liquid crystal panel of the liquid crystal display includes a liquid crystal layer and a TFT substrate and a color filter substrate opposite each other in the state in which the liquid crystal layer is interposed therebetween, wherein a picture is displayed using light provided from a backlight unit.

An active matrix type organic light-emitting display has come onto the market as an example of the electroluminescent device. Since the organic light-emitting display is self-emissive, the organic light-emitting display has no backlight, compared to the liquid crystal display, and has merits in terms of response time and viewing angle, and therefore the organic light-emitting display has attracted attention as a next-generation display.

Recently, the preference for a display device that is not fixed but freely movable is increasing. There is a need to increase work efficiency while freely moving a display device location in an office, and there is a need for a display device that can meet both portability and convenience of mounting or holding for outdoor use such as camping, etc.

### SUMMARY

### Technical Problem

Accordingly, embodiments of the present disclosure are directed to a display device that substantially obviates one or more problems due to limitations and disadvantages of the related art.

### Technical Solutions

Provided is a display device including: a body housing having a display that outputs an image mounted on a front surface thereof; each strap ring formed on a side surface of the body housing; a strap having opposite ends fastened to the strap rings, respectively; an elastic holder including a strap hole where the strap is fitted; and a pair of holder coupling portions defined in a rear surface of the body housing, wherein opposite ends of the elastic holder are inserted into the pair of holder coupling portions, respectively, wherein the elastic holder supports the rear surface of the body housing and allows the body housing to stand on a mounting surface when the opposite ends thereof are respectively inserted into the pair of holder coupling portions.

The elastic holder may include: a metal plate deformable in a longitudinal direction thereof; and a cushion made of an elastic material double-injected onto the metal plate.

The metal plate may include a rigid bead extending in the longitudinal direction thereof, and the rigid bead may include a plurality of rigid beads arranged side by side in a width direction thereof.

The strap hole may be defined in the cushion.

The elastic holder may include: a curved surface bent outwards; and each fixing groove defined in an outer surface of the cushion and fitted into each holder coupling portion when inserted into each holder coupling portion.

The strap rings may be positioned at opposite ends of a long side of the main housing, respectively, and the pair of holder coupling portions may be adjacent to each other in a direction of the long side of the main housing.

The strap rings may be positioned at opposite ends of a first long side of the main housing, and the holder coupling portions may be positioned adjacent to a second long side positioned opposite to the first long side.

A length of the strap may be equal to or greater than a sum of twice a distance from each strap ring to each holder coupling portion and a length of the elastic holder.

The holder coupling portions may be defined in the side surface of the body housing.

### Advantageous Effects

According to at least one embodiment of the display device of the present disclosure, carrying and mounting are available with one elastic holder, thereby improving portability and usability.

In addition, according to at least one embodiment of the display device of the present disclosure, because the mounting structure is not complicated and large, an exterior design may be simplified and the number of members may be reduced.

In addition, according to at least one embodiment of the display device of the present disclosure, a support force may be secured using the metal plate 1451 that is deformable in one direction.

A display device of the present disclosure is advantageous in terms of space utilization because there is little restriction on a mounting location and it can be mounted in a narrow space.

A display device of the present disclosure may mount a camera module without a separate cable, thereby providing a work environment optimized for video meetings and the like.

Effects obtainable from the present disclosure may be non-limited by the above-mentioned effects. And, other unmentioned effects can be clearly understood from the following description by those having ordinary skill in the technical field to which the present disclosure pertains.

### BRIEF DESCRIPTION OF THE DRAWINGS

FIG. 1 is a block diagram illustrating components of a display device according to the present disclosure;

FIG. 2 is a perspective view illustrating a coupling aspect of a strap of the display device according to an embodiment of the present disclosure;

FIG. 3 is a diagram illustrating an elastic holder of the display device according to an embodiment of the present disclosure;

FIG. 4 is a diagram illustrating a metal plate of the elastic holder of the display device according to an embodiment of the present disclosure;

FIGS. 5 to 7 are diagrams illustrating a method for fastening the elastic holder of the display device according to an embodiment of the present disclosure to stand holes;

FIG. 8 is a diagram illustrating another embodiment of the elastic holder of the display device according to an embodiment of the present disclosure; and

FIG. 9 is a diagram illustrating a state in which the elastic holder of the display device according to an embodiment of the present disclosure is fastened to handle holes.

### BEST MODE

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

Meanwhile, an image display device 100 described in this specification is, for example, an intelligent image display device 100 having a computer supporting function in addition to a broadcast reception function, wherein an Internet function may be added while the broadcast reception function is devotedly performed, whereby an interface that is more conveniently used, such as a handwriting type input device, a touchscreen, or a space remote control, may be provided. In addition, the image display device may be connected to the Internet or a computer through support of a wired or wireless Internet function, whereby various functions, such as e-mail, web browsing, banking, or gaming, may be executed. For such various functions, a standardized general-purpose OS may be used.

In the image display device described in the present disclosure, therefore, various applications may be freely added or deleted, for example, on a general-purpose OS kernel, whereby various user friendly functions may be executed. More specifically, the image display device may be a network TV, an Hbb TV, or a smart TV, and is applicable to a smartphone depending on circumstances.

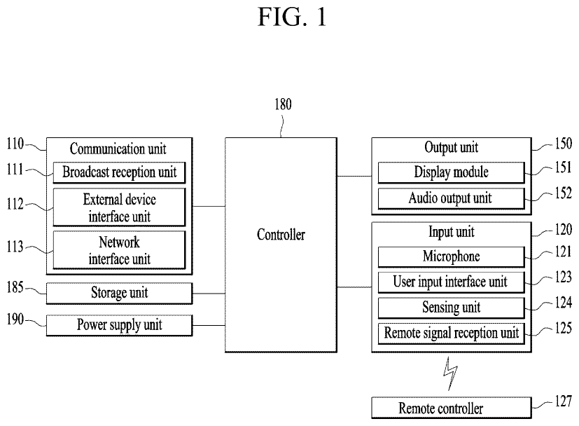

FIG. 1 is a block diagram illustrating components of a display device 100.

The display device 100 may include a communication unit 110, an input unit 120, a sensing unit 124, an output unit 150, a controller 180, a storage unit 185, and a power supply unit 190. The configuration shown in FIG. 1 may include only some of the components, and one configuration may perform two functions.

The communication unit 110 may include a broadcast reception unit 111 including a tuner unit and a demodulator. The tuner unit of the broadcast reception unit 111 may select a broadcast signal corresponding to a channel selected by a user or any one of all pre-stored channels, among broadcast signals received through an antenna (not shown) or a cable (not shown). The tuner unit 111 may convert the selected broadcast signal into an intermediate frequency signal or a baseband video or audio signal.

Meanwhile, the tuner unit may sequentially select broadcast signals of all broadcast channels stored through a channel memory function, among received broadcast signals, and may convert each of the selected broadcast signals into an intermediate frequency signal or a baseband video or audio signal

The demodulation unit of the broadcast reception unit 111 may receive the digital IF (DIF) signal converted by the tuner unit, and may perform demodulation. After performing demodulation and channel decryption, the demodulation unit may output a stream signal (TS). At this time, the stream signal may be a multiplexed image, audio, or data signal.

The stream signal output from the demodulation unit may be input to the controller 180. After performing demultiplexing and image/audio signal processing, the controller 180 may output an image through the display module 151, and may output audio through the audio output unit 152.

An external device interface unit 112 may connect an external device to the display device 100 to receive an image signal, an audio signal, and a control signal from the external device. The interface unit 112 may be connected by wire/wireless to external devices such as a Digital Versatile Disk (DVD), a Blu-ray, a game device, a camera, a camcorder, a computer (laptop), and the like.

The external device interface unit 112 transmits video, audio, or data signals inputted externally to the controller 180 of the display device 100 through the connected external device. In addition, the video, audio, or data signals processed by the controller 180 may be outputted to the connected external device.

The external device interface unit 112 may include a wired type and a wireless type. The wired type includes a physical terminal provided to the display device 100, and the wireless type may be connected to an external device through an antenna that receives a wireless signal.

The wired type may include a USB terminal, a Composite Video Banking Sync (CVBS) terminal, a component terminal, an S-video terminal (analog), a Digital Visual Interface (DVI) terminal, a High Definition Multimedia Interface (HDMI) terminal, an RGB terminal, a D-SUB terminal, and so on.

The wireless type may perform short-range wireless communication with other electronic devices located nearby. The display device 100 may be connected to other electronic devices via networks according to communication standards such as Bluetooth, Radio Frequency Identification (RFID), Infrared Data Association (IrDA), Ultra Wideband (UWB), ZigBee, Digital Living Network Alliance (DLNA), etc.

The network interface unit 113 may access a prescribed web page through a connected network or another network linked to the connected network. That is, the network interface unit 113 may transmit and receive data with a corresponding server by accessing the prescribed web page through the network. In addition, the network interface unit 113 may receive contents or data provided by a content provider or a network operator.

That is, contents such as movies, advertisements, games, VODs, and broadcast signals provided from content providers or network providers and information related to such contents may be received through the network. In addition, update information and update files of firmware provided by the network operator may be received. In addition, data may be transmitted to the Internet or content provider or network operator.

In addition, the network interface unit 113 may select a desired application from applications opened to the public and receive the selected application through the network.

According to an embodiment, when a game application is executed in the display device, the network interface unit 113 may transmit or receive prescribed data to or from a user terminal connected to the display device via the network. Also, prescribed data may be transmitted or received with a server that stores game scores

The input unit 120 may include a microphone 121 that collects sound, a user input unit 123 that detects a user's command, a sensor unit that senses a state and surrounding state of the display device, and a remote signal reception unit 125 that receives a signal of a remote controller 127.

The microphone 121 may recognize a user's voice or surrounding sound, and in particular, receive a user's voice and process it as electrical audio data. Various noise cancellation algorithms for removing noise generated in the process of receiving an external audio signal may be implemented in the microphone 121.

The microphone 121 may simply collect user's voice, convert the collected voice into audio data, and store it in the storage unit 185 or transmit it to the external device via the communication unit 110, and may also perform a function as the user input unit 123 in a manner of analyzing the audio data and recognizing it as a user command.

In addition to the main body of the display device 100, the microphone 121 may be mounted on the remote controller 127, which will be described later, and the corresponding audio data may be forwarded to the controller 180 through the remote signal reception unit 125.

The user input unit 123 is a device to which a user inputs a control command for controlling the display device. The user input unit 123 may include a keypad, a button, a touch pad, a touch screen, etc.

When the user input unit 123 includes a hard key button, a user may input a command related to the display device 100 through a push operation of the hard key button. When the user input unit 123 is provided with a touchscreen, the user may input a command related to display device 100 to remote controller 127 by touching the soft key of the touchscreen.

In addition, the user input unit 123 may include various types of input means that the user can operate, such as a scroll key, a jog key, etc., and the present embodiment does not limit the scope of the right of the present disclosure.

Recently, as the size of a bezel of the display device 100 decreases, the display device 100 tends to minimize the user input unit 123 of the physical button type exposed externally. Instead, a minimum physical button is located on a rear side or a lateral side, and a user input may be received from a touchpad or the remote controller 127 through a remote signal reception unit 125 that will be described later.

The remote signal reception unit 125 may input a command related to the display device 100 through the remote controller 127 having the user input unit 123. The remote signal reception unit 125 is a sort of the user input unit 123 and may belong to a wireless communication unit because it receives signals from the remote controller 127 according to various communication methods such as Radio Frequency (RF) communication method, Infrared (IR) communication method, etc.

The sensing unit 124 refers to a device that detects a change in the display device 100 or an external change. For example, the sensing unit 124 may include at least one of a proximity sensor, an illumination sensor, a touch sensor, an Infrared (IR) sensor, an ultrasonic sensor, an optical sensor (e.g., a camera), a voice sensor (e.g., a microphone), a battery gauge, an environment sensor (e.g., a hygrometer, a thermometer, etc.), and the like.

Recently, a display device 100 that can move or change a direction of a display has emerged, and a gyro sensor, an acceleration sensor and the like may be provided to detect a posture of the display device.

Based on the information collected by the sensing unit 124, the controller 180 may check the state of the display device 100 and notify a user of a problem when the problem occurs or adjust it by itself, thereby controlling the display device 100 to maintain a best state.

In addition, the content, image quality, and size of an image provided to the display module 151 may be controlled differently depending on a viewer, a surrounding illumination and the like sensed by the sensing unit 124, thereby providing an optimal viewing environment. As smart TVs advance, functions mounted on the display device increase, and the sensing unit 124 is also increasing correspondingly.

The output unit 150 is a device that provides visual and auditory information to a user through the display device, and may include the display module 151 and the audio output unit 152.

The display module 151 may convert an image signal, a data signal, an OSD signal, and a control signal processed by the controller 180 or an image signal, a data signal, and a control signal received from the interface unit to generate a driving signal. The display module 151 may include a display panel having a plurality of pixels.

Each of the plurality of pixels in the display panel may include RGB subpixels. Alternatively, each of the plurality of pixels in the display panel may include RGBW subpixels. The display module 151 may convert an image signal, a data signal, an OSD signal, and a control signal processed by the controller 180 to generate a driving signal for the plurality of pixels.

A plasma display panel (PDP), a liquid crystal display (LCD), an organic light-emitting diode (OLED), or a flexible display may be used as the display module 151, and a 3D display may also be used. The 3D display 130 may be classified as a non-glasses type display or a glasses type display.

The display device 100 includes a display module 151, which occupies a major portion of the front surface thereof, and a case configured to cover the rear surface and the side surface of the display module 151, the case being configured to package the display module 151.

In recent years, the display device 100 has used a flexible display module 150, such as light-emitting diodes (LED) or organic light-emitting diodes (OLED), in order to implement a curved screen.

Light is supplied to an LCD, which was mainly used conventionally, through a backlight unit, since the LCD is not self-emissive. The backlight unit is a device that supplies light emitted from a light source to a liquid crystal uniformly located in front thereof. As the backlight unit has been gradually thinned, a thin LCD has been implemented. However, it is difficult to implement the backlight unit using a flexible material. If the backlight unit is curved, it is difficult to supply uniform light to the liquid crystal, whereby the brightness of a screen is changed.

In contrast, the LED or the OLED may be implemented so as to be curved, since an element constituting each pixel is self-emissive, and therefore no backlight unit is used. In addition, since each element is self-emissive, the brightness of the element is not affected even though the positional relationship between adjacent elements is changed, and therefore it is possible to implement a curved display module 150 using the LED or the OLED.

An organic light-emitting diode (OLED) panel appeared in earnest in mid 2010 and has rapidly replaced the LCD in the small- or medium-sized display market. The OLED is a display manufactured using a self-emissive phenomenon of an organic compound in which the organic compound emits light when current flows in the organic compound. The response time of the OLED is shorter than the response time of the LCD, and therefore afterimages hardly appear when video is implemented.

The OLED is an emissive display product that uses three fluorescent organic compounds having a self-emissive function, such as red, green, and blue fluorescent organic compounds and that uses a phenomenon in which electrons injected at a negative electrode and a positive electrode and particles having positive charges are combined in the organic compounds to emit light, and therefore a backlight unit, which deteriorates color, is not needed.

A light-emitting diode (LED) panel is based on technology of using one LED element as one pixel. Since it is possible to reduce the size of the LED element, compared to a conventional device, it is possible to implement a curved display module 150. The conventional device, which is called an LED TV, uses the LED as a light source of a backlight unit that supplies light to the LCD, and therefore the LED does not constitute a screen.

The display module includes a display panel and a coupling magnet, a first power supply unit, and a first signal module located at a rear surface of the display panel. The display panel may include a plurality of pixels R, G, and B. The plurality of pixels R, G, and B may be formed at intersections between a plurality of data lines and a plurality of gate lines. The plurality of pixels R, G, and B may be disposed or arranged in a matrix form.

For example, the plurality of pixels R, G, and B may include a red subpixel ‘R’, a green subpixel ‘G’, and a blue subpixel ‘B’. The plurality of pixels R, G, and B may include a white subpixel ‘W’.

The side of the display module 150 on which a picture is displayed may be referred to as a front side or a front surface. When the display module 150 displays the picture, the side of the display module 150 from which the picture cannot be viewed may be referred to as a rear side or a rear surface. Meanwhile, the display module 150 may be constituted by a touchscreen, whereby an input device may also be used in addition to an output device.

The audio output unit 152 receives an audio signal processed by the controller 180 and outputs the same as audio.

The controller 180 may include at least one processor, and may control the overall operation of the display device 100 using the processor included therein. Here, the processor may be a general processor, such as a central processing unit (CPU). Of course, the processor may be a dedicated device, such as an ASIC, or another hardware-based processor.

The controller 180 may demultiplex a stream input through the tuner unit, the demodulation unit the external device interface unit 112, or the network interface unit 113, or may process demultiplexed signals to generate and output a signal for image or audio output.

An image signal processed by the controller 180 may be input to the display module 151, which may display an image corresponding to the image signal. In addition, the image signal processed by the controller 180 may be input to an external output device through the external device interface unit 112.

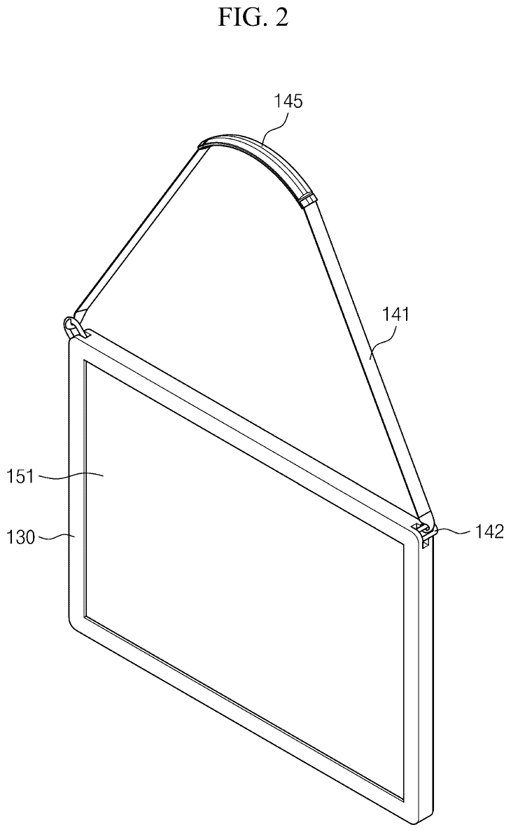

An audio signal processed by the controller 180 may be output through the audio output unit 152. In addition, the audio signal processed by the controller 180 may be input to an external output device through the external device interface unit 112. Although not shown in FIG. 2, the controller 180 may include a demultiplexing unit and an image processing unit.

Further, the controller 180 may control the overall operation of the display device 100. For example, the controller 180 may control the tuner unit such that a broadcast corresponding to a channel selected by a user or a pre-stored channel is tuned.

In addition, the controller 180 may control the display device 100 according to a user command input through the user input interface unit or an internal program. Meanwhile, the controller 180 may control the display module 151 to display an image. At this time, the image displayed on the display module 151 may be a still image or video, or may be a 2D image or a 3D image.

Meanwhile, the controller 180 may perform control such that a predetermined 2D object is displayed in an image displayed on the display module 151. For example, the object may be at least one of a connected web screen (newspaper or magazine), an electronic program guide (EPG), various menus, a widget, an icon, a still image, video, and text.

Meanwhile, the controller 180 may modulate and/or demodulate a signal using an amplitude shift keying (ASK) method. Here, the amplitude shift keying (ASK) method may be a method of changing the amplitude of a carrier depending on a data value to modulate a signal or restoring an analog signal to a digital data value depending on the amplitude of a carrier.

For example, the controller 180 may modulate an image signal using the amplitude shift keying (ASK) method, and may transmit the modulated image signal through a wireless communication module.

For example, the controller 180 may demodulate and process an image signal received through the wireless communication module using the amplitude shift keying (ASK) method.

As a result, the display device 100 may easily transmit and receive a signal to and from another image display device disposed adjacent thereto without using a unique identifier, such as a media access control (MAC) address, or a complicated communication protocol, such as TCP/IP.

Meanwhile, the display device 100 may further include a photographing unit (not shown). The photographing unit may photograph a user. The photographing unit may be implemented by one camera; however, the present disclosure is not limited thereto. The photographing unit may be implemented by a plurality of cameras. Meanwhile, the photographing unit may be embedded in the display device 100 above the display module 151, or may be separately disposed. Image information photographed by the photographing unit may be input to the controller 180.

The controller 180 may recognize the location of a user based on an image captured by the photographing unit. For example, the controller 180 may recognize the distance between the user and the display device 100 (z-axis coordinate). Further, the controller 180 may recognize an x-axis coordinate and a y-axis coordinate in the display module 151 corresponding to the location of the user.

The controller 180 may sense user gesture based on the image captured by the photographing unit, a signal sensed by the sensor unit, or a combination thereof.

The storage unit 185 may store programs for signal processing and control in the controller 180, and may store a processed image, audio, or data signal. For example, the storage unit 185 may store application programs designed to execute various tasks that can be processed by the controller 180, and may selectively provide some of the stored application programs in response to request of the controller 180.

Programs stored in the storage unit 185 are not particularly restricted as long as the programs can be executed by the controller 180. The storage unit 185 may temporarily store an image, audio, or data signal received from an external device through the external device interface unit 171. The storage unit 185 may store information about a predetermined broadcast channel through a channel memory function, such as a channel map.

FIG. 1 shows an embodiment in which the storage unit 185 and the controller 180 are separately provided; however, the present disclosure is not limited thereto. The storage unit 185 may be included in the controller 180.

The storage unit 185 may include at least one of a volatile memory (e.g. DRAM, SRAM, or SDRAM), a nonvolatile memory (e.g. flash memory), a hard disk drive (HDD), and a solid-state drive (SSD).

The power supply unit 190 may supply power to the components of the display device 100. In particular, the power supply unit may supply power to the controller 180, which may be implemented in the form of a system on chip (SOC), the display module 150 for image display, and the audio output unit 160 for audio output.

Specifically, the power supply unit 190 may include an AC/DC converter (not shown) configured to convert AC power into DC power and a DC/DC converter (not shown) configured to convert the level of the DC power.

Meanwhile, the power supply unit 190 serves to distribute power supplied from the outside to the respective components of the display device. The power supply unit 190 may be directly connected to an external power supply in order to supply AC power, or may include a battery so as to be used by charging.

In the former case, a cable is used, and the power supply unit is difficult to move or the movement range of the power supply unit is limited. In the latter case, the power supply unit is free to move, but the weight of the power supply unit is increased in proportion to the weight of the battery, the volume of the power supply unit is increased, and, for charging, the power supply unit must be directly connected to a power cable or must be coupled to a charging holder (not shown) that supplies power for a predetermined time.

The charging holder may be connected to the display device through a terminal exposed to the outside, or the battery mounted in the power supply unit may be charged in a wireless manner when the power supply unit approaches the charging holder.

Meanwhile, the block diagram of the display device 100 shown in FIG. 1 is for an embodiment of the present disclosure, and elements of the block diagram may be integrated, added, or omitted depending on specifications of an actually implemented display device 100.

That is, two or more elements may be integrated into one element, or one element may be divided into two or more elements, as needed. In addition, the function performed by each block is for describing the embodiment of the present disclosure, and the specific operations and components thereof do not limit the scope of rights of the present disclosure.

As a thickness of a display device 100 has recently decreased, the device has become lighter in weight, and thus a frequency of using the display device in a mobile situation has increased resulting from growing popularity of camping and outdoor activities. However, an existing structure of the display device with a fixed stand has a great volume and thus has a limited mobility, and does not have a separate handle for carrying the display device.

Accordingly, the present disclosure is intended to provide the display device 100 that is portable and is easily mountable without the separate stand. FIG. 2 is a perspective view illustrating a coupling aspect of a strap 141 of the display device 100 according to an embodiment of the present disclosure. The display device 100 may be transported using the strap 141.

A strap ring 142 for connecting the strap 141 to a side portion 130a of a body housing 130 of the display device 100 may be included. The strap ring 142 may be located at a corner of the body housing 130, and may include at least two strap rings 142.

When the strap rings 142 are disposed at three corners, respectively, as illustrated in FIG. 2, the strap 141 may be connected to strap rings 142 respectively located at opposite ends of a long side, or the strap 141 may be connected to strap rings 142 respectively located at opposite ends of a short side (not illustrated).

The strap 141 may be connected to the display device 100 in a form that facilitates a movement of the display device. When the strap 141 is worn over a shoulder, the movement of the display device is convenient. The strap ring 142 may not necessarily be located at the corner, but may be located on a side surface of the body housing 130.

Even when the display device 100 is lightweight, it may still cause discomfort on the shoulder in contact with the strap 141 due to a weight thereof. In order to solve such inconvenience, an elastic holder 145 may be further included in the middle of the strap 141.

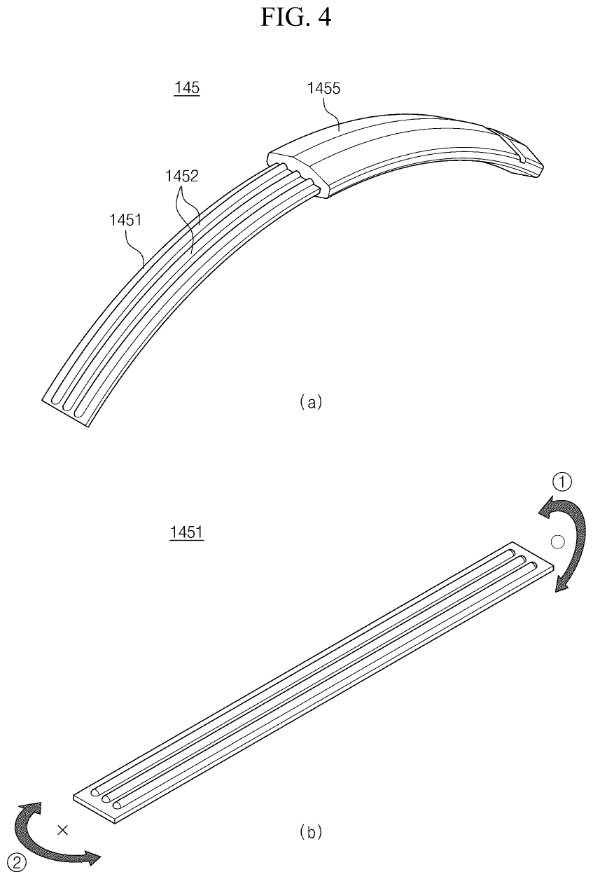

The elastic holder 145 may include an elastic material, and may be integrally formed with the strap 141 or may be detachable from the strap 141. FIG. 4 is a diagram illustrating the elastic holder 145 of the display device 100 according to an embodiment of the present disclosure. (a) is a diagram illustrating an end of the elastic holder 145, and (b) is a diagram illustrating deformation of the elastic holder 145.

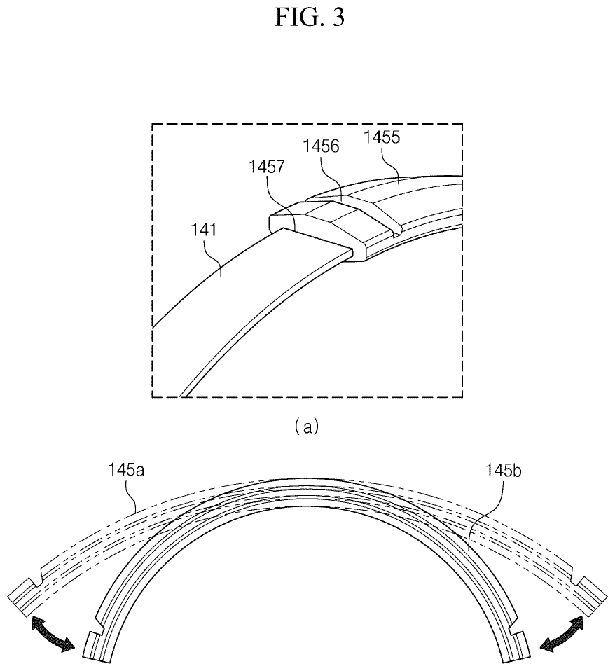

As illustrated in (a) in FIG. 3, the elastic holder 145 may include a strap hole 1457 into which the strap 141 is fitted, and the strap 141 may extend through the elastic holder 145 in a longitudinal direction of the elastic holder 145.

The elastic holder 145 is deformable, and may include a flexible material such as silicone. As illustrated in (b) in FIG. 3, the elastic holder 145 may be changed in a curvature in the longitudinal direction thereof.

When the strap 141 is not worn, the elastic holder 145a may have a gentle first curvature, and when the strap 141 is worn over the shoulder, a force may be concentrated on a central portion of the elastic holder 145, so that the elastic holder 145b may be bent and the curvature may increase to a second curvature.

The elastic holder 145 should be free to deform in the longitudinal direction thereof so that, when worn over the shoulder, it may be stably seated on the shoulder as the curvature thereof changes.

FIG. 4 is a diagram illustrating a metal plate 1451 of the elastic holder 145 of the display device 100 according to an embodiment of the present disclosure. As illustrated in (a) in FIG. 4, the elastic holder 145 may include a cushion 1455 made of an elastic material such as silicon and the metal plate 1451 positioned therein. The cushion 1455 may be manufactured using a double injection molding scheme such that the metal plate 1451 is located therein, and the cushion 1455 may be integrally formed with the metal plate 1451.

Because the cushion 1455 has elasticity, it may improve wearing comfort on the user's shoulder and distribute an applied force. Both a strap hole 1457 and a fixing groove 1456 to be described later may be defined in the cushion 1455, and the metal plate 1451 may be located inside the cushion 1455 and may not be exposed to the outside.

The metal plate 1451 is a plate-shaped member made of a metal material, and has a great length in a longitudinal direction thereof and a relatively small length in a width direction thereof. As illustrated in (b) in FIG. 4, a curvature change in the longitudinal direction \textcircled{1} may easily occur, but because the length is small in the width direction, a curvature change in the width direction \textcircled{2} does not easily occur.

In order to further limit the curvature change in the width direction, as illustrated in (a) in FIG. 4, a plurality of rigid beads 1452 extending in a longitudinal direction thereof and arranged side by side in a width direction thereof may be further included.

The rigid beads 1452 are formed by pressing one surface of the metal plate 1451, so that they protrude from an opposite surface of the metal plate 1451. Further, the rigid beads 1452 increase rigidity of the metal plate 1451. Although the rigid beads 1452 are also elastically deformable when a length thereof is great in one direction, they may further reinforce the rigidity of the metal plate 1451 and limit deformation of the metal plate 1451 in a direction in which they have a small length.

The metal plate 1451 may be manufactured in a bent state to have a first curvature in the longitudinal direction when there is no external force, and may be configured to maintain the first curvature even in a state in which no force is applied to the elastic holder 145.

The elastic holder 145 of the present disclosure may serve not only to distribute a force of pressurizing the shoulder by being fitted with the strap 141, but also to serve as a stand that allows the display device 100 to stand on a mounting surface.

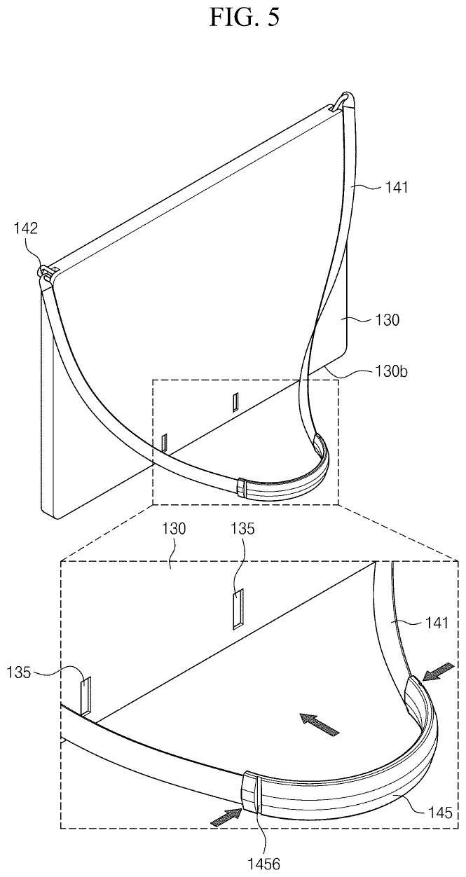

FIGS. 5 to 7 are diagrams illustrating a method for fastening the elastic holder 145 of the display device 100 according to an embodiment of the present disclosure to a holder coupling portion 135. The holder coupling portion 135 may be positioned in a rear surface of the body housing 130 of the display device 100. The holder coupling portion 135 may be positioned close to a long side 130b of the body housing 130 and may include a pair of holes adjacent to each other in a direction of the long side.

Opposite ends of the elastic holder 145 may be inserted into the holder coupling portions 135, respectively. When the opposite ends of the elastic holder 145 are respectively inserted into the holder coupling portions 135, the elastic holder 145 may be pressed at both sides thereof so as to have a curvature greater than the first curvature. As illustrated in (b) in FIG. 3, when bending deformation is performed such that a spacing between the opposite ends of the elastic holder 145 corresponds to a spacing between the holder coupling portions 135, the opposite ends of the elastic holder 145 may be respectively inserted into the holder coupling portions 135.

As illustrated in (a) in FIG. 3, the elastic holder 145 may have the fixing grooves 1456 defined therein so as to be respectively fitted into the holder coupling portions 135. The fixing grooves 1456 may be defined on an outer side in a direction in which the elastic holder 145 is bent, and may be respectively fitted into the pair of holder coupling portions 135 from an outer side thereof.

As the elastic holder 145 is widened by a force to restore the first curvature, which is an original curvature, the fixing grooves 1456 are respectively fitted into the holder coupling portions 135 and are not deviated from the holder coupling portions 135.

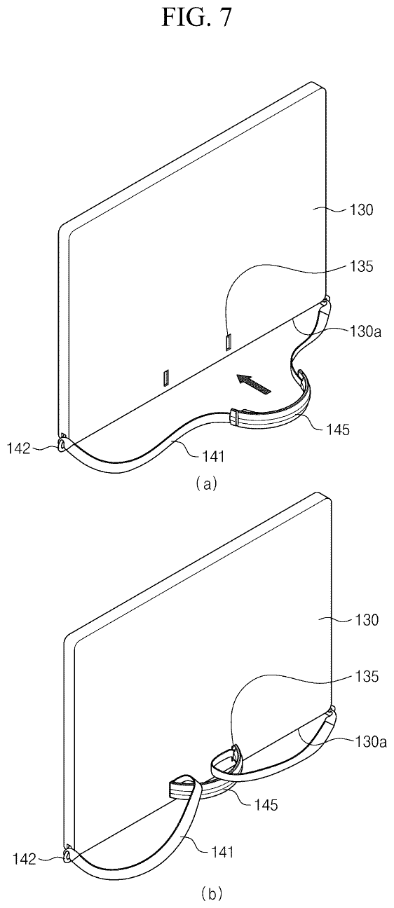

As described above, because a change in the width direction of the elastic holder 145 is limited, the elastic holder 145 is not deformed even when the display device 100 is inclined rearwards and a force is applied in the width direction of the elastic holder 145 as illustrated in FIG. 7, thereby supporting the display device 100.

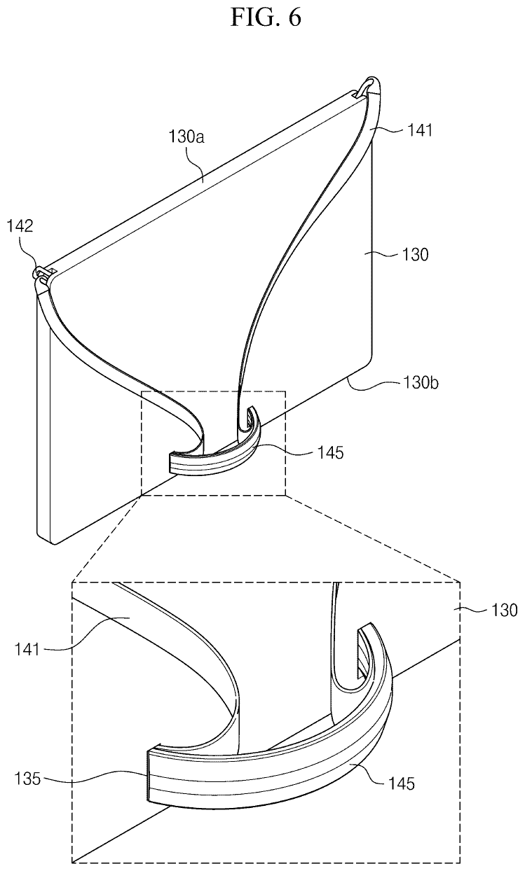

The elastic holder 145 may be inserted into the holder coupling portions by removing the strap 141 therefrom, but because it is cumbersome to remove and engage the strap 141, the elastic holder 145 may be coupled to the holder coupling portions 135 while opposite ends of the strap 141 being respectively connected to the strap rings 142 as illustrated in FIG. 6.

As illustrated in FIG. 6, when a length of the strap 141 is sufficiently great, the holder coupling portions may be positioned adjacent to a second long side 130b opposite to a first long side 130a where the strap rings 142 are positioned. However, even when the length of the strap 141 is small, the holder coupling portions 135 may be defined adjacent to the first long side 130a where the strap rings 142 are positioned as illustrated in FIG. 7 such that the elastic holder 145 may be coupled to the holder coupling portions 135.

The length of the strap 141 may be equal to or greater than a sum of twice a distance from the strap ring 142 to the holder coupling portion 135 and a length of the elastic holder 145.

Referring to (a) in FIG. 3, opposite ends of the strap hole 1457 into which the strap 141 is inserted may be positioned at the opposite ends of the elastic holder 145. In this case, when the elastic holder 145 is inserted into the holder coupling portions, the strap 141 may be partially inserted into the holder coupling portions 135. When the strap 141 is twisted, it may be difficult to be inserted into the holder coupling portions 135, so that coupling to the holder coupling portions 135 needs to be performed after the strap 141 and the elastic holder 145 are arranged such that their surface directions coincide with each other.

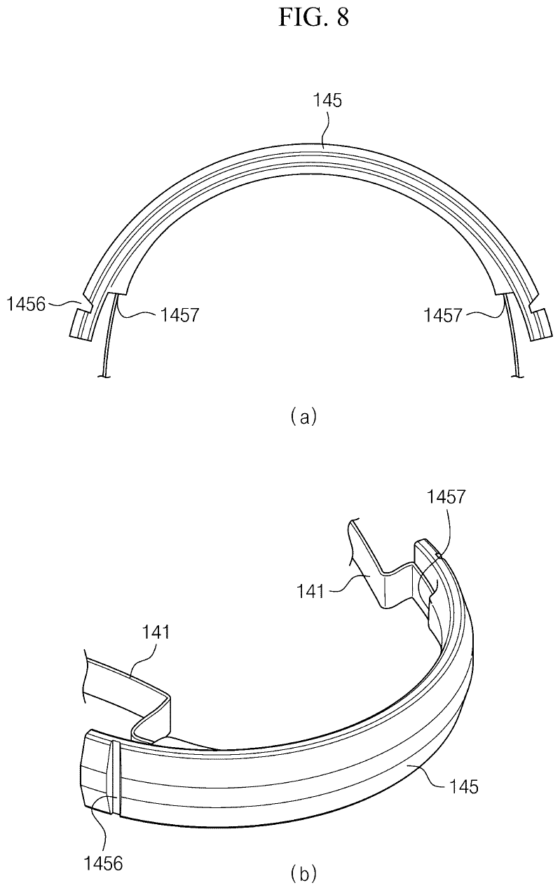

FIG. 8 is a diagram illustrating another embodiment of the elastic holder 145 of the display device 100 according to an embodiment of the present disclosure.

The strap hole 1457 may be defined at a position farther from the end of the elastic holder 145 than the fixing groove 1456, rather than at the end of the elastic holder 145. When the elastic holder 145 is inserted into the holder coupling portions, because the opposite ends of the strap hole 1457 are not inserted into the holder coupling portions 135, the strap 141 may not be inserted into the holder coupling portions 135.

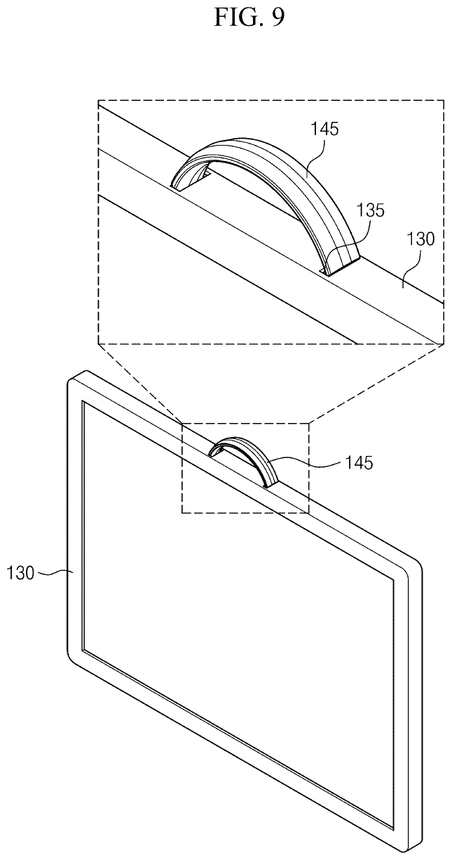

Although FIG. 9 illustrates that a step is formed, only the end of the strap hole 1457 may be defined at a position slightly spaced apart from the end of the elastic holder 145 without the step and overlapping of the holder coupling portion 135 and the strap 141 may be avoided.

FIG. 9 is a diagram illustrating a state in which the elastic holder 145 of the display device 100 according to an embodiment of the present disclosure is fastened to handle holes. Holder coupling portions 135 defined in the side surface of the body housing 130 of the display device 100 may be further included as illustrated in FIG. 9.

Unlike the shape that the holder coupling portions are defined in the rear surface of the body housing 130, the holder coupling portions 135 may be located in the side surface of the body housing 130, and the elastic holder 145 may serve as a handle. The holder may be gripped by hand to carry the display device 100. Depending on convenience of a person carrying the device, the strap 141 may be used in a form worn over the shoulder, as illustrated in FIG. 2, or in a form of a hand-held handle, as illustrated in FIG. 9.

According to at least one embodiment of the display device 100 of the present disclosure, carrying and mounting are available with one elastic holder 145, thereby improving portability and usability.

In addition, because the mounting structure is not complicated and large, an exterior design may be simplified and the number of members may be reduced.

In addition, a support force may be secured using the metal plate 1451 that is deformable in one direction.

The display device 100 of the present disclosure is advantageous in terms of space utilization because there is little restriction on a mounting location and the display device 100 can be mounted in a narrow space.

The above detailed description should not be construed as being limitative in all terms, but should be considered as being illustrative. The scope of the present invention should be determined by reasonable analysis of the accompanying claims, and all changes in the equivalent range of the present invention are included in the scope of the present invention.

1. A display device comprising:
a body housing having a display configured to output an image mounted on a front surface thereof;
each strap ring formed on a side surface of the body housing;
a strap having opposite ends fastened to the strap rings, respectively;
an elastic holder including a strap hole where the strap is fitted; and
a pair of holder coupling portions defined in a rear surface of the body housing, wherein opposite ends of the elastic holder are inserted into the pair of holder coupling portions, respectively,
wherein the elastic holder is configured to support the rear surface of the body housing and allow the body housing to stand on a mounting surface when the opposite ends thereof are respectively inserted into the pair of holder coupling portions.

2. The display device of claim 1, wherein the elastic holder includes:
a metal plate deformable in a longitudinal direction thereof; and
a cushion made of an elastic material double-injected onto the metal plate.

3. The display device of claim 2, wherein the metal plate includes a rigid bead extending in the longitudinal direction thereof,
wherein the rigid bead includes a plurality of rigid beads arranged side by side in a width direction thereof.

4. The display device of claim 2, wherein the strap hole is defined in the cushion.

5. The display device of claim 2, wherein the elastic holder includes:
a curved surface bent outwards; and
each fixing groove defined in an outer surface of the cushion and fitted into each holder coupling portion when inserted into each holder coupling portion.

6. The display device of claim 1, wherein the strap rings are positioned at opposite ends of a long side of the main housing, respectively,
wherein the pair of holder coupling portions are adjacent to each other in a direction of the long side of the main housing.

7. The display device of claim 6, wherein the strap rings are positioned at opposite ends of a first long side of the main housing,
wherein the holder coupling portions are positioned adjacent to a second long side positioned opposite to the first long side.

8. The display device of claim 6, wherein a length of the strap is equal to or greater than a sum of twice a distance from each strap ring to each holder coupling portion and a length of the elastic holder.

9. The display device of claim 1, wherein the holder coupling portions are defined in the side surface of the body housing.
